(19) United States
(12) Patent Application Publication
(10) Pub. No.: US 2019/0011074 A1
(43) Pub. Date: Jan. 10, 2019

(54) THERMAL PROTECTION SYSTEM UTILIZING INSULATING AND CONDUCTIVE MATERIALS

(71) Applicant: Stryke Industries, LLC, Fort Wayne, IN (US)

(72) Inventors: Ian Fuller, Bellbrook, OH (US); Van Flamion, Warsaw, IN (US)

(73) Assignee: Stryke Industries, LLC, Fort Wayne, IN (US)

(21) Appl. No.: 15/992,783

(22) Filed: May 30, 2018

Related U.S. Application Data
(60) Provisional application No. 62/528,638, filed on Jul. 5, 2017.

(51) Int. Cl. F16L 59/02; B32B 7/12; B32B 9/00; B32B 5/16; G01R 27/08; C01B 32/05

(52) U.S. Cl. CPC F16L 59/029; B32B 7/12; B32B 9/007; B32B 5/16; G01R 27/08; C01P 2006/32; C01B 32/05; B32B 2264/10; B32B 2305/026; B32B 2307/302; B32B 2307/202; F16L 59/028

(57) ABSTRACT

A thermal protection system includes an outer coating layer, at least one inner bond coat layer, and a conductive layer positioned adjacent at least one of the outer coating layer and the at least one bond coat layer.

### CROSS-REFERENCE TO RELATED APPLICATION

The present application claims priority to U.S. Provisional Patent Application No. 62/528,638, filed Jul. 5, 2017, entitled THERMAL PROTECTION SYSTEM UTILIZING INSULATION AND CONDUCTIVE MATERIALS, the complete disclosure of which is expressly incorporated herein by reference.

### FIELD OF THE DISCLOSURE

This invention relates generally to a thermal protection system for markets such as aerospace, automotive, electronics, industrial, and the like. More specifically, the invention relates to a thermally conductive layer placed in working contact with a bond layer and/or a thermally insulating ceramic layer used to inhibit heat flow into or about the underlying substrate material.

### BACKGROUND OF THE PRESENT DISCLOSURE

In current applications where high temperatures and/or high heat fluxes may be experienced, a thermal barrier coating (TBC) is often applied to components to inhibit heat flow and insulate the underlying substrate material. For example, yttria stabilized zirconia (YSZ) is a thermally insulating ceramic material utilized in such high-temperature applications due to its relatively low thermal conductivity and relatively high coefficient of thermal expansion. This YSZ, or other ceramic layer, is often applied to an alloy bond coat, one such example of which is the formulation MCrAlY, where M is comprised of one or more of the following metals: iron, cobalt, or nickel. The bond coat layer helps maximize adhesion between the ceramic and the underlying substrate material, reduce thermal-cycle fatigue, and may also provide additional thermal oxidation and corrosion resistance. The bond coat reduces thermal-cycle fatigue by accommodating stress buildup that may result from the coefficient of thermal expansion mismatch between the substrate and the insulating layer.

Additionally, known thermal barrier coatings may be applied via deposition processes including electron beam physical vapor deposition, chemical vapor deposition, plasma spray, vacuum plasma spray, low-pressure plasma spray, shrouded plasma spray, atmospheric plasma spray, high velocity oxygen fuel, and similar.

Currently, TBCs are employed in a number of industries including automotive and aerospace but have potential application anywhere that reducing thermal transfer is desired or necessary. Currently, TBCs used within gas turbine engines have allowed for continual increases in combustion temperatures which is strongly correlated with overall turbine efficiency. High nickel content superalloys, high performance alloys exhibiting excellent mechanical strength, resistance to thermal creep deformation, and high melting points, are often employed as the turbine blades with TBC coatings that allow for turbine operation above the melting point of the superalloy.

While traditional TBCs do significantly reduce the heat transfer from the external environment into the substrate material, they do little to dissipate the heat parallel to the surface or reduce temperature gradients within the substrate. The lack of thermal dissipation parallel to the substrate results in known shortcomings in industries that utilize TBCs. Specifically, applications that experience localized heating often experience premature degradation of both the coating and the underlying substrate material. More particularly, localized heating results in internal stress build-up due to thermal expansion mismatches and temperature gradients. Furthermore, this thermal localization results in mechanical weakening and/or thermally induced oxidation or corrosion of the substrate material, which often has a melting or softening temperature far below that of the outside environment.

The type, thickness, and properties of the insulating layer play a critical role in determining the amount of thermal energy transferred into the substrate and the rate of said transfer. Once the thermal energy reaches the substrate surface, it is dissipated throughout the bulk of the substrate only as rapidly as the thermal diffusion of the substrate will allow (17-4PH stainless steel, for example, has a thermal conductivity of 20 W/m-K).

Therefore, there is a need for the ability to first insulate, and then rapidly wick heat away from the areas of elevated temperature to minimize TBC coating thickness (and thereby cost and weight). Additionally, according to the present disclosure, it may be possible to minimize the thickness of the underlying metal components as thermal diffusion, rapid oxidation, and ablation issues are reduced.

### SUMMARY OF THE DISCLOSURE

To this end, the present disclosure pertains to synergistically combining a substrate material, at least one bond coat, one or more highly thermal conductive layers (highly thermally conductive as compared to the insulating ceramic layer) in working contact with said at least one bond coat and/or said substrate material, and an insulating ceramic layer applied over said highly thermally conductive layer(s) and/or said at least one bond coat. As thermal energy is transferred through the insulating ceramic layer, the underlying thermally conductive layer quickly and efficiently spreads the heat away from the “hot points” such that it is evenly distributed across a much larger surface area. The present disclosure enhances the effectiveness of TBCs and provides system designers with the opportunity to operate in ever more extreme temperature environments and/or reduce cost, weight, or other pertinent characteristics.

According to one embodiment of the present disclosure, a thermal protection system includes an outer coating layer, at least one bond coat layer, and a conductive layer positioned adjacent at least one of the outer coating layer and the at least one bond coat layer.

In one aspect of the thermal protection system, the at least one bond coat layer includes a first bond coat layer and a second bond coat layer, and the first bond coat layer is positioned intermediate the outer coating layer and the conductive layer, and the second bond coat layer is positioned inward of the outer coating layer, the conductive layer, and the first bond coat layer.

In another aspect of the thermal protection system, the conductive layer is positioned in a first position defined intermediate the outer coating layer and the at least one bond coat layer.

In yet another aspect of the thermal protection system, the conductive layer is positioned in a second position defined inward of both the at least one bond coat layer and the outer coating layer.

In a further aspect of the thermal protection system, the conductive layer is comprised of at least one of a ceramic material, and a metallic material.

In another aspect of the thermal protection system, the conductive layer is comprised of approximately 98 wt. % or more of carbon.

In yet another aspect of the thermal protection system, the conductive layer is porous.

In a further aspect of the thermal protection system, the conductive layer includes a coating.

In another aspect of the thermal protection system, the thermal protection system further comprises an adhesive positioned adjacent at least one of the conductive layer, the at least one bond coat layer, and the outer coating layer.

In yet another aspect of the thermal protection system, a surface of the conductive layer is mechanically abraded.

In a further aspect of the thermal protection system, a surface energy of the conductive layer is one of increased and decreased to promote adhesion between the conductive layer and at least one of the outer coating layer and the at least one bond coat layer.

In another aspect of the thermal protection system, the outer coating layer is comprised of a ceramic material having a thermal conductivity up to 5 W/m-K.

In yet another aspect of the thermal protection system, the outer coating layer is adjacent the at least one bond coat layer and the outer coating layer and the at least one bond coat layer are combined to create a single layer including a gradient transition, where both the at least one bond coat and the outer coating layer are simultaneously present at varying ratios throughout the single layer.

In a further aspect of the thermal protection system, the conductive layer is thermally conductive.

In another aspect of the thermal protection system, the conductive layer is both thermally conductive and electrically conductive.

According to another embodiment of the present disclosure, a method for measuring a temperature-dependent property of a thermal protection system includes applying a voltage to a conductive layer of the thermal protection system, wherein the conductive layer is positioned at one of a first position defined intermediate an outer coating layer and at least one bond coat layer and a second position defined inward of both the outer coating layer and the at least one bond coat layer, measuring a current of the conductive layer when the voltage is applied, calculating the resistance of the conductive layer based on the measured current, and determining a temperature of the conductive layer of the thermal protection system based on the calculated resistance.

In one aspect of the method, the temperature-dependent property is a temperature of the conductive layer.

In another aspect of the method, the temperature-dependent property is a strain of the conductive layer.

According to yet another embodiment of the present disclosure, a method for applying heat to a thermal protection system includes applying a voltage to a conductive layer of the thermal protection system sufficient to provide resistive heating of the thermal protection system, wherein the conductive layer is positioned at one of a first position defined intermediate an outer coating layer and at least one bond coat layer and a second position defined inward of both the outer coating layer and the at least one bond coat layer.

In one aspect of the method, the conductive layer is positioned at the first position defined intermediate the outer coating layer and the at least one bond coat layer.

### BRIEF DESCRIPTION OF THE DRAWINGS

The above mentioned and other features of this invention, and the manner of attaining them, will become more apparent and the invention itself will be better understood by reference to the following description of embodiments of the invention taken in conjunction with the accompanying drawings, where:

FIG. 1 is a schematic view of a thermal protection system of the present disclosure, including an insulating ceramic layer, a thermally conductive layer, a bond coat layer, and a substrate;

FIG. 2 is another schematic view of an alternative embodiment of a thermal protection system of the present disclosure, including an insulating ceramic layer, a bond coat layer, a thermally conductive layer, and a substrate;

FIG. 3 is another schematic view of yet another alternative embodiment of a thermal protection system of the present disclosure, including an insulating ceramic layer, a first bond coat layer, a thermally conductive layer, a second bond coat layer, and a substrate;

FIG. 4 is another schematic view of yet another alternative embodiment of a thermal protection system of the present disclosure, including an insulating ceramic layer, a porous thermally conductive layer, a bond coat layer, and a substrate;

FIG. 5 is a schematic view of the thermal protection system of FIG. 1, illustrating thermal gradients within the substrate; and

FIG. 6 is a schematic view of a prior art thermal barrier coating which does not include the thermally conductive layer of the present disclosure.

Corresponding reference characters indicate corresponding parts throughout the several views. Although the drawings represent embodiments of the present invention, the drawings are not necessarily to scale and certain features may be exaggerated in order to better illustrate and explain the present invention.

### DETAILED DESCRIPTION OF THE DRAWINGS

The embodiments disclosed below are not intended to be exhaustive or to limit the invention to the precise forms disclosed in the following detailed description. Rather, the embodiments are chosen and described so that others skilled in the art may utilize their teachings. Unless specifically noted or clearly implied otherwise, the term “approximately” refers to a range of values of plus or minus 5%, e.g., about 100 refers to the range 95 to 105.

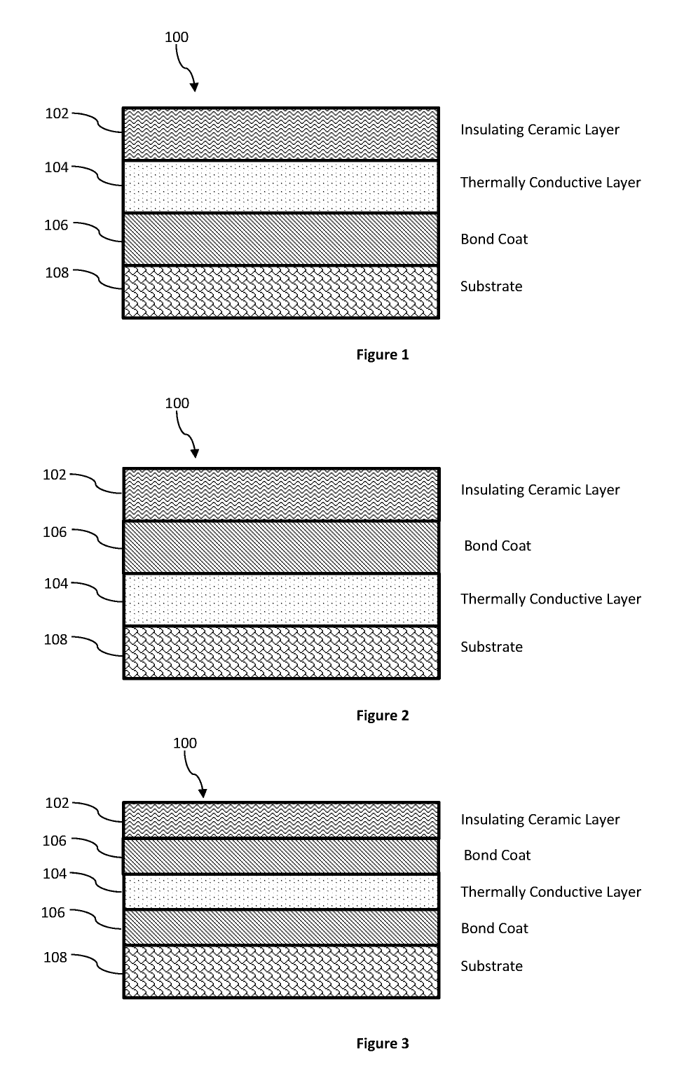

The present disclosure relates to a thermal protection system comprised of at least one layer of material applied to a substrate. For example, and referring to FIGS. 1-5, the thermal protection system 100 of the present disclosure may include an insulating ceramic layer 102, a thermally conductive layer 104, and at least one bond coat layer 106 positioned adjacent one another and applied to a substrate 108. Illustratively, insulating ceramic layer 102 may be defined as the outermost layer of the thermal protection system and is spaced apart from the substrate 108 by the thermally conductive layer 104 and the bond coat 106. Additionally, in one embodiment, the illustrative thermally conductive layer 104 is positioned at a first position defined intermediate a lowermost or innermost surface of the insulating ceramic layer 102 and an outermost or uppermost surface of the bond coat 106. In another embodiment, the illustrative thermally conductive layer 104 is positioned at a second position defined inward of both bond coat 106 and insulating ceramic layer 102, and intermediate a lowermost or innermost surface of the bond coat 106 and an outermost or uppermost surface of the substrate 108. Also, in one embodiment, the bond coat 106 is positioned intermediate the substrate 108 and the thermally conductive layer 104 such that the outermost or uppermost surface of the bond coat 106 is in contact with the thermally conductive layer 104 and the innermost or lowermost surface of the bond coat 106 is in contact with the substrate 108. In another embodiment, the bond coat 106 is positioned intermediate the lowermost or innermost surface of the insulating ceramic layer 102 and an outermost or uppermost surface of the thermally conductive layer 104. In one embodiment, the thermal protection system 100 includes multiple layers of bond coat 106, where a first layer of bond coat 106 is positioned intermediate the lowermost or innermost surface of the insulating ceramic layer 102 and an outermost or uppermost surface of the thermally conductive layer 104, and a second layer of bond coat 106 is positioned intermediate the lowermost or innermost surface of the thermally conductive layer 104 and the outermost or uppermost surface of the substrate 108. It may be appreciated that the insulating ceramic layer 102, thermally conductive layer 104, and the bond coat 106 may be applied consecutively or simultaneously to each other and/or the substrate 108. In one embodiment, the substrate 108 may be comprised of a metallic material and may be used in various industries, such as the aerospace, automotive, or electrical industries. Alternatively, the substrate 108 may be comprised of a polymeric, ceramic material, and/ or an elastomeric material for various applications. In various embodiments, the substrate 108 may be comprised of a combination of any of the above materials.

With respect to the thermally conductive layer 104 of the thermal protection system 100, the thermally conductive layer 104 is comprised of a highly thermally conductive material including, but not limited to copper, aluminum, chromium, beryllium, magnesium, nickel, silver, gold, graphite, graphene, carbon nanotubes, carbon fiber, highly oriented pyrolytic graphite (HOPG), diamond, annealed pyrolytic graphite (APG), boron nitride, and combinations thereof. In various embodiments, thermally conductive layer 104 is comprised of 0-100 wt. % of carbon. In one example, conductive layer 104 is comprised of approximately 98 wt. % or more of carbon, while in another example conductive layer 104 is comprised of approximately 3 wt. % or less. In one embodiment, the thermally conductive layer may be non-porous. The thermal conductivity of the thermally conductive layer may be either isotropic or anisotropic, depending on the application requirements. These thermally conductive materials have high thermal conductivity as compared to insulating ceramic materials traditionally used in thermal barrier coatings (TBCs) (for example, HOPG: anisotropic, in-plane thermal conductivity of up to 2,000 W/m-K; Copper: isotropic thermal conductivity of up to 450 W/m-K; Diamond: in-plane thermal conductivity of up to 3,320 W/m-K). In general, the greater the thermal conductivity of the thermally conductive layer 104, the better the layer can dissipate heat. In various embodiments, the thermal conductivity of thermally conductive layer 104 may be as little as 20 W/m-K, 30 W/m-K, 40 W/m-K or 50 W/m-K, or as great as 2,220 W/m-K, 2,720 W/m-K, or 3,320 W/m-K, or within any range defined between any two values therebetween, such as approximately 20 W/m-K to approximately 3,320 W/m-K, approximately 50 W/m-K to approximately 2,720 W/m-K, or approximately 450 W/m-K to approximately 2,000 W/m-K, for example.

The thermally conductive layer 104 of the thermal protection system 100 may be configured as a coating, a particulate material, a sheet good or planar member such as a porous mat, foil, or perforated foil, a fiber or series of fibers, or any combination thereof. In general, the greater the thickness of thermally conductive layer 104, the better the layer can dissipate heat. In various embodiments, thermally conductive layer 104 may be as low as 5 μm, 10 μm, or 15 μm, or as great as 150 μm, 200 μm, or 250 μm, or within any range defined between any two values therebetween, such as approximately 5 μm to approximately 250 μm, approximately 15 μm to approximately 200 μm, or approximately 50 μm to approximately 180 μm, for example. In one embodiment, thermally conductive layer 104 is configured as a coating which may be applied through plasma spray, wire arc spray, cold spray, chemical vapor deposition, physical vapor deposition, electroless plating, electrophoresis, electroplating, evaporation, or similar deposition techniques. In various embodiments, the coating may be applied in one or multiple applications to achieve the desired thickness and grain size of the coating.

When the thermally conductive layer 104 is incorporated as a sheet good, an adhesive or a coating may be employed to securely adhere the thermally conductive layer 104 to the bond coat 106 prior to application of the insulating ceramic layer 102 and/or adhere thermally conductive layer 104 to insulating ceramic layer 102 and/or substrate 108. A diagram showing the working relationship between the different layers is given in FIGS. 1-4. The coating may include or comprise of nickel, palladium, copper, aluminum, titanium, chromium, gold, silver, platinum or combinations thereof, and may be applied through any of the deposition techniques listed above, while the adhesive may include or comprise a polymeric adhesive and/or a high temperature ceramic and graphite adhesive. In various embodiments, the thickness of the coating may be approximately 5×10⁻⁶ inch or greater.

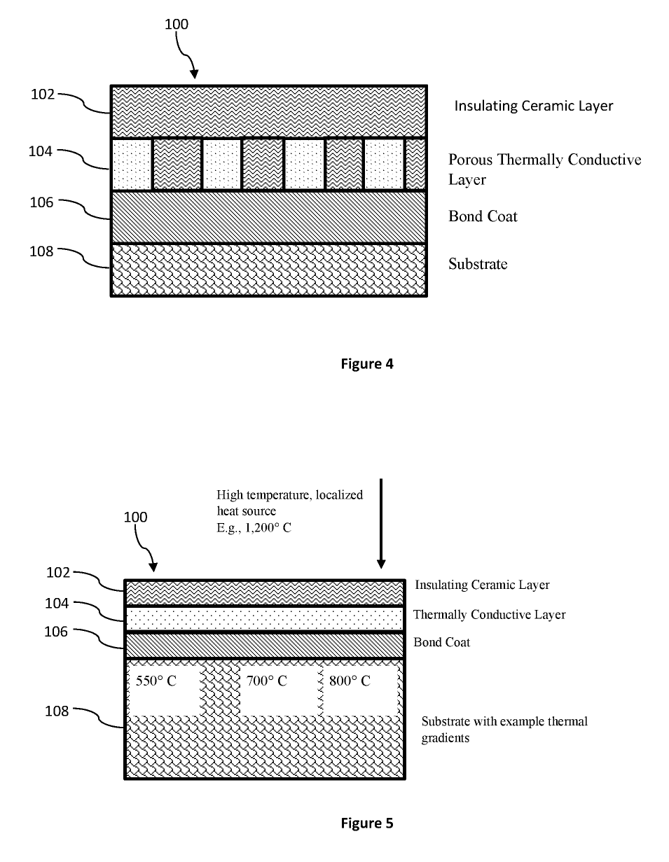

As shown in FIG. 4, one embodiment of the present disclosure may utilize a porous thermally conductive layer 104 so as to maintain a degree of connection and mechanical adhesion between the layers adjacent thermally conductive layer 104, for example, the insulating ceramic layer 102 and the bond coat 106. This porous conductive layer may have tailorable porosity to suit the end-application requirements. For example, the porosity of the thermally conductive layer may be between 1%-95%, 5%-90%, 10%-80%, 20%-70%, 30%-60%, 40%-50%, or any value delimited in any combination of the aforementioned ranges. The utilization of a porous conductive layer may reduce or eliminate the requirement for an adhesive layer or coating, as the adhesion through the conductive layer may be facilitated by the porosity of the thermally conductive layer. For example, the porous thermally conductive layer 104 may facilitate adhesion or coupling between the insulating ceramic layer 102 and the bond coat 106 in a manner sufficient for the application requirements by allowing the insulating ceramic layer 102 and the bond coat 106 to adhere to each other generally through the pores of the thermally conductive layer 104. In various embodiments, the porous thermally conductive layer 104 may include a coating. The coating may include perforations or openings that align with the pores of porous thermally conductive layer 104 to allow direct adhesion between the adjoining layers through both porous thermally conductive layer 104 and the coating. In various embodiments, the perforations or openings in the coating may be formed after a uniform coating is applied to the porous thermally conductive layer 104 such that the perforations or openings match the pores of the porous thermally conductive layer 104, while in other various embodiments, pores in thermally conductive layer 104 and the coating may be formed at the same time. The pores and/or perforations of thermally conductive layer 104 and/or the coating may be formed using various processes, for example etching, water jetting, laser perforation, and mechanical cutting.

In various embodiments, thermally conductive layer 104 may be mechanically abraded and/or have its surface energy modified to promote adhesion between thermally conductive layer 104 and its surrounding layers. The surface energy of thermally conductive layer 104 may be increased or decreased such that the surface energy of one of the layers is greater than that of an adhesive or other material or layer(s) to increase or promote adhesion of the adhesive or other material or layer(s) to the layer. For example, the surface energy of the conductive layer may be increased such that it is greater than the surface energy of the bond coat to increase or promote adhesion of the bond coat to the conductive layer, or the surface energy of the conductive layer may be decreased such that it is less than the surface energy of the bond coat to increase or promote adhesion of the conductive layer to the bond coat. In various embodiments, the surface energy of the thermally conductive layer may be modified via plasma, corona treatment, acid etching, or other similar processes. The modification of the surface energy may include a chemical change at the surface of the layer to add or remove different functional groups which modifies the surface energy for better adhesion or coupling.

Referring still to FIGS. 1-4, the insulating ceramic layer 102 may be comprised of any ceramic material with low thermal conductivity (i.e., 5 W/m-K or less) including, but not limited to, yttria-stabilized zirconia (YSZ) having approximately 2-10 wt % yttria, lanthanum zirconate (LZ), zirconia, alumina, ceria (CeO₂), mullite (3Al₂O₃2SiO₂ or 2Al₂O₃ SiO₂), silica (SiO₂), hafnia (HfO₂), niobium oxide, lanthanum oxide (La₂O₃), praseodymium oxide, pyrochlore oxides (A₂³⁺B₂⁴⁺O₇, where A and B are metals), and combinations thereof. In various embodiments, oxides used in the ceramic layer may be doped with one or more trivalent transition metal ions. Thicknesses for the insulating ceramic layer 102 may be 1 μm to 1cm, or any range therein, for example 250-500 μm.

With reference still to FIGS. 1-4, the bond coat layer 106 may be comprised of the formulation MCrAlY, where M is comprised of one or more of the following metals: iron, cobalt, nickel, tantalum, rhenium, or combinations thereof. Additions of rhenium or tantalum may be incorporated into the bond coat 106 for additional performance enhancements. Thicknesses for the bond coat 106 may be between 1-150 μm, or any range therein, for example 1-75 μm or 75-120 μm.

In addition to discrete layers, the present invention may include multiple layers combined to create a single combined layer having a gradient transition between the multiple layers such that the materials of each of the multiple layers are simultaneously present in varying ratios throughout the single combined layer. For example, the bond coat and the insulating ceramic layer and/or the thermally conductive layer and the bond coat may be at least partially combined to create a single combined layer having a gradient transition such that the bond coat and the insulating ceramic layer and/or the thermally conductive layer and the bond coat are both simultaneously present at varying ratios throughout the single combined layer. In various embodiments, the single combined layer is formed between a layer of the first pure material and a layer of the second pure material, while in other various embodiments, the a single combined layer incorporates all of the first material and the second material. For example, the single combined layer of the bond coat and the insulating ceramic layer may be formed intermediate a thinner layer of the bond coat and a thinner layer of the insulating ceramic layer, or the single combined layer may incorporate all of both the bond coat layer and the insulating ceramic layer.

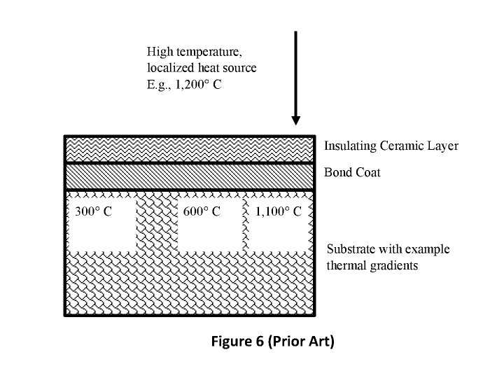

Compared to known thermal barrier coating technology, the thermal protection system of the present disclosure has the ability to reduce localized substrate temperatures and minimize stress induced by large temperature gradients because the thermally conductive layer allows for heat dissipation across the substrate, thereby reducing localized “hot spots”. To illustrate this concept, example temperatures are given in FIG. 5 and FIG. 6. For example, FIG. 5 illustrates that the thermally conductive layer of the thermal protection system of the present disclosure has a thermal effect on substrate temperatures as compared to FIG. 6, without said thermally conductive layer. More particularly, the prior art TBC of FIG. 6 does not include the thermally conductive layer of the present disclosure and, therefore, the substrate experiences a significant thermal gradient at the point of localized heating. Illustratively, if localized heat is applied to a portion of the substrate at a temperature of 1,200° C., because the TBC (i.e., the combination of the insulating ceramic layer and the bond coat) does not include a thermally conductive layer, the heat remains localized at that portion of the substrate such that the substrate experiences thermal levels substantially similar to that of the heat source itself, for example, 1,100° C.

However, with respect to FIG. 5, in which the thermal protection system does include the thermally conductive layer of the present disclosure, the localized heat (e.g., 1,200° C.) applied to a portion of the substrate is dissipated throughout the thermally conductive layer such that the heat experienced by the substrate at the location of the heat source is reduced to approximately 800° C., for example. In this way, other portions of the substrate may experience elevated heating, such as those portions illustratively shown at 700° C. and 550° C., such that it is clear that the thermally conductive layer of the present disclosure dissipates or spreads the heat from the localized heat source throughout other portions of the substrate, thereby decreasing the thermal load at the localized heat source. Additionally, because the substrate is configured for high-temperature applications, the thermally conductive layer may decrease the thermal load on the substrate at the localized heat source such that the thermal load experienced by the all portions of the substrate are within a specified range for the substrate. As such, the life of the substrate may be increased by use of the thermal protection system of the present disclosure. Also, the time under which the substrate is exposed to high temperatures may be increased due to the thermally conductive layer of the thermal protection system.

When thermal protection system 100 of the present disclosure is electrically conductive, system 100 may also be used as a sensor and/or to apply heat to the system 100 and/or adjacent materials. In order for thermal protection system 100 to be used as a sensor, a voltage is applied across conductive layer 104. While the voltage is applied across conductive layer 104, a current is measured, and a resistance is then calculated based on the measured current. The calculated resistance is proportional to a temperature-dependent property of layer 104. For example, the temperature-dependent property may include the temperature of layer 104 and/or the strain of layer 104.

In order for thermal protection system 100 to be used to apply heat to the system and/or adjacent materials, a voltage is applied across conductive layer 104 sufficient for resistive heating of layer 104 and thus adjacent layers. The heat applied by conductive layer 104 may be sufficient to inhibit ice growth or melt ice adjacent system 100.

While this invention has been described as having an exemplary design, the present invention may be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains.

What is claimed is:

1. A thermal protection system comprising:
an outer coating layer;
at least one bond coat layer; and
a conductive layer positioned adjacent at least one of the outer coating layer and the at least one bond coat layer.

2. The thermal protection system of claim 1, wherein the at least one bond coat layer includes a first bond coat layer and a second bond coat layer, the first bond coat layer positioned intermediate the outer coating layer and the conductive layer, and the second bond coat layer positioned inward of the outer coating layer, the conductive layer, and the first bond coat layer.

3. The thermal protection system of claim 1, wherein the conductive layer is positioned in a first position defined intermediate the outer coating layer and the at least one bond coat layer.

4. The thermal protection system of claim 1, wherein the conductive layer is positioned in a second position defined inward of both the at least one bond coat layer and the outer coating layer.

5. The thermal protection system of claim 1, wherein the conductive layer is comprised of at least one of a ceramic material, and a metallic material.

6. The thermal protection system of claim 5, wherein the conductive layer is comprised of approximately 98 wt. % or more of carbon.

7. The thermal protection system of claim 1, wherein the conductive layer is porous.

8. The thermal protection system of claim 1, wherein the conductive layer includes a coating.

9. The thermal protection system of claim 8 further comprising an adhesive positioned adjacent at least one of the conductive layer, the at least one bond coat layer, and the outer coating layer.

10. The thermal protection system of claim 1, wherein a surface of the conductive layer is mechanically abraded.

11. The thermal protection system of claim 1, wherein a surface energy of the conductive layer is one of increased and decreased to promote adhesion between the conductive layer and at least one of the outer coating layer and the at least one bond coat layer.

12. The thermal protection system of claim 1, wherein the outer coating layer is comprised of a ceramic material having a thermal conductivity up to 5 W/m-K.

13. The thermal protection system of claim 1, wherein the outer coating layer is adjacent the at least one bond coat layer and the outer coating layer and the at least one bond coat layer are combined to create a single layer including a gradient transition, where both the at least one bond coat and the outer coating layer are simultaneously present at varying ratios throughout the single layer.

14. The thermal protection system of claim 1, wherein the conductive layer is thermally conductive.

15. The thermal protection system of claim 14, wherein the conductive layer is both thermally conductive and electrically conductive.

16. A method for measuring a temperature-dependent property of a thermal protection system including:
applying a voltage to a conductive layer of the thermal protection system, wherein the conductive layer is positioned at one of a first position defined intermediate an outer coating layer and at least one bond coat layer and a second position defined inward of both the outer coating layer and the at least one bond coat layer;
measuring a current of the conductive layer when the voltage is applied;
calculating the resistance of the conductive layer based on the measured current; and
determining the temperature-dependent property of the conductive layer of the thermal protection system based on the calculated resistance.

17. The method of claim 16, wherein the temperature-dependent property is a temperature of the conductive layer.

18. The method of claim 16, wherein the temperature-dependent property is a strain of the conductive layer.

19. A method for applying heat to a thermal protection system including:
applying a voltage to a conductive layer of the thermal protection system sufficient to provide resistive heating of the thermal protection system, wherein the conductive layer is positioned at one of a first position defined intermediate an outer coating layer and at least one bond coat layer and a second position defined inward of both the outer coating layer and the at least one bond coat layer.

20. The method of claim 19, wherein the conductive layer is positioned at the first position defined intermediate the outer coating layer and the at least one bond coat layer.
